(19) United States
(12) Patent Application Publication
(10) Pub. No.: US 2014/0183444 A1
(43) Pub. Date: Jul. 3, 2014

(54) HIGH-VOLTAGE FLIP-CHIP LED STRUCTURE AND MANUFACTURING METHOD THEREOF

(71) Applicant: HELIO OPTOELECTRONICS CORPORATION, Zhudong Town (TW)

(72) Inventors: Ming-Hung CHEN, Zhudong Town (TW); Shih-Chang Shei, Zhudong Town (TW)

(73) Assignee: HELIO OPTOELECTRONICS CORPORATION, Zhudong Town (TW)

(21) Appl. No.: 13/781,256

(22) Filed: Feb. 28, 2013

(30) Foreign Application Priority Data
Dec. 28, 2012 (TW) 101151003

(51) Int. Cl. H01L 33/46; H01L 27/15

(52) U.S. Cl. CPC H01L 33/46; H01L 27/153
USPC 257/13; 438/29

(57) ABSTRACT

A high-voltage flip-chip LED structure and a manufacturing method thereof are disclosed. The manufacturing method includes: providing a die substrate, depositing a first passivation layer, forming a co-electrical-connecting layer, depositing a second passivation layer, depositing a mirror layer, forming two conductive tunnels by etching, and providing two connecting metal layers. The die substrate includes a sapphire substrate and multiple LED chips thereon. The fully transparent co-electrical-connecting layer, formed after formation of the first passivation layer, electrically connects the LED chips in series. The outer surface of the deposited second passivation layer is a flat passivation surface that enables the mirror layer thereon to be level and reflect light without optical path difference. The two connecting metal layers are provided for electrical conduction. The high-voltage flip-chip LED structure thus formed has fully transparent electrodes and can output light without optical path difference.

### BACKGROUND OF THE INVENTION

1. Technical Field

The present invention relates to a light-emitting diode structure and a manufacturing method thereof. More particularly, the present invention relates to a high-voltage flip-chip light-emitting diode structure and a manufacturing method thereof.

2. Description of Related Art

Recognized for their compactness, high performance, and environmental friendliness, light-emitting diodes (LEDs) have recently become the mainstream products in the lighting market. Therefore, all major LED manufacturers are now devoted to developing LED structures of even higher light emission efficiency and high yield rate, and manufacturing processes thereof.

FIG. 1 shows a conventional flip-chip LED structure. As shown in FIG. 1, the conventional flip-chip LED structure 100 includes: an LED substrate 110, an N-electrode 150, a P-electrode 160, bond pads 140, a blocking layer 180, a reflecting layer 120, a patterned insulating layer 170, a conducting layer 190, and an epitaxial layer 130, wherein the epitaxial layer 130 includes: an N-type semiconductor layer 131, a light-emitting layer 132, and a P-type semiconductor layer 133. To increase light extraction efficiency, the conventional flip-chip LED structure 100 is so designed that the light emitted backward by the light-emitting layer 132 will be reflected forward by the reflecting layer 120. However, as the different parts of the reflecting layer 120 are at different levels, the reflected light has an optical path difference.

Nowadays, a high-voltage LED structure can be made by connecting a plurality of LED-chip epitaxial structures in series, and it is well known in the art that a high-voltage LED structure enables simplification of the LED packaging process, features increased light emission efficiency, and has a great potential in the future lighting market. Therefore, it is highly desirable to have a high-voltage flip-chip LED structure which is derived from the existing high-voltage LED structure and capable of overcoming the aforesaid problem of optical path difference.

### BRIEF SUMMARY OF THE INVENTION

The present invention discloses a high-voltage flip-chip LED structure and a manufacturing method thereof, wherein the manufacturing method includes the steps of: providing a die substrate, depositing a first passivation layer, forming a co-electrical-connecting layer, depositing a second passivation layer, depositing a mirror layer, forming two conductive tunnels by etching, and providing two connecting metal layers. The present invention is intended to provide a high-voltage flip-chip LED structure whose electrodes are fully transparent and whose reflecting layer lies in a single plane.

The present invention provides a manufacturing method of a high-voltage flip-chip light-emitting diode (LED) structure, comprising the steps of: providing a die substrate, wherein the die substrate comprises: a sapphire substrate, and a plurality of LED chips formed on the sapphire substrate and spaced from one another, each said LED chip being formed, from bottom to top, by an N-type layer, a quantum well layer, a P-type layer, and a transparent conductive oxide layer, each said N-type layer having an exposed N-type surface, the LED chips comprising a first LED chip and a second LED chip; depositing a first passivation layer on exposed surfaces of the LED chips; forming a co-electrical-connecting layer by: removing the first passivation layer on each said transparent conductive oxide layer and on each said N-type surface, and then forming a first electrical connecting layer on each said transparent conductive oxide layer, a second electrical connecting layer on each said N-type surface, and a third electrical connecting layer connecting the first electrical connecting layer of a said LED chip and the second electrical connecting layer of an adjacent said LED chip, wherein the first electrical connecting layer, the second electrical connecting layer, and the third electrical connecting layer constitute the co-electrical-connecting layer; depositing a second passivation layer on the first passivation layer and on the co-electrical-connecting layer such that a flat passivation surface is formed; depositing a mirror layer on the passivation surface; forming two conductive tunnels by: etching downward from the mirror layer to the first electrical connecting layer of the first LED chip, and etching downward from the mirror layer to the second electrical connecting layer of the second LED chip; and providing two connecting metal layers by: filling each said conductive tunnel with a connecting metal, and providing the connecting metal layers onto the mirror layer such that the connecting metal layers are respectively connected to the connecting metals and are spaced from each other.

The present invention also provides a high-voltage flip-chip light-emitting diode (LED) structure, comprising: a die substrate comprising: a sapphire substrate, and a plurality of LED chips formed on the sapphire substrate and spaced from one another, each said LED chip being formed, from bottom to top, by an N-type layer, a quantum well layer, a P-type layer, and a transparent conductive oxide layer, each said N-type layer having an exposed N-type surface, the LED chips comprising a first LED chip and a second LED chip; a first passivation layer provided on lateral sides of each said LED chip; a co-electrical-connecting layer comprising: a first electrical connecting layer located on each said transparent conductive oxide layer, a second electrical connecting layer located on each said N-type surface, and a third electrical connecting layer connecting a said first electrical connecting layer and an adjacent said second electrical connecting layer and covering the first passivation layer on a said lateral side of each said LED chip; a second passivation layer enclosing the first passivation layer and the co-electrical-connecting layer such that a flat passivation surface is formed; a mirror layer provided on the passivation surface; two connecting metals extending through the mirror layer and the second passivation layer and respectively connected to the first electrical connecting layer of the first LED chip and the second electrical connecting layer of the second LED chip; and two connecting metal layers provided on the mirror layer, respectively connected to the connecting metals, and spaced from each other.

Implementation of the present invention at least produces the following advantageous effects:

1. A flip-chip LED structure with fully transparent electrodes can be obtained for increased light emission efficiency.

2. The reflecting layer of the resulting flip-chip LED structure lies in a single plane to reduce optical path difference.

The detailed features and advantages of the present invention will be described in detail with reference to the preferred embodiment so as to enable persons skilled in the art to gain insight into the technical disclosure of the present invention, implement the present invention accordingly, and readily understand the objectives and advantages of the present invention by perusal of the contents disclosed in the specification, the claims, and the accompanying drawings.

### BRIEF DESCRIPTION OF THE SEVERAL VIEWS OF THE DRAWINGS

The present invention will be best understood by referring to the following detailed description of some illustrative embodiments in conjunction with the accompanying drawings, in which:

FIG. 1 schematically shows a conventional flip-chip LED structure;

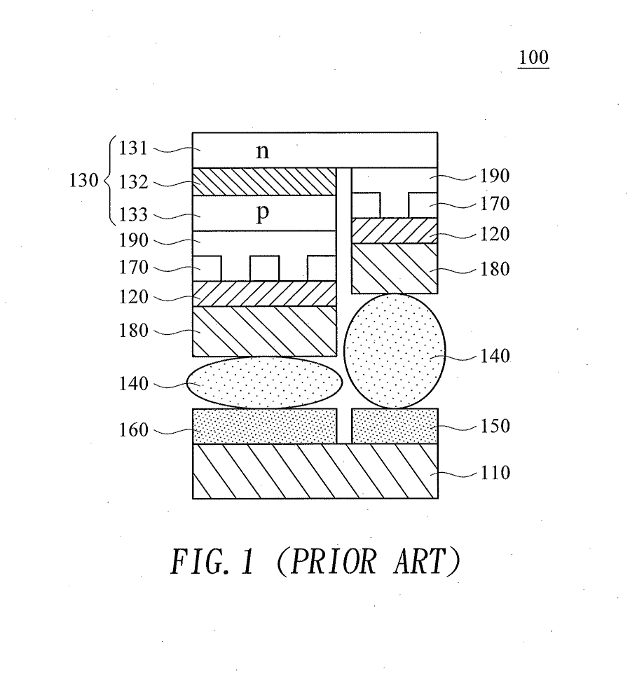

FIG. 2 is the flowchart of a manufacturing method of a high-voltage flip-chip LED structure according to an embodiment of the present invention;

FIG. 3 is a sectional view showing the step of providing a die substrate according to an embodiment of the present invention;

FIG. 4 is a sectional view showing the step of depositing a first passivation layer according to an embodiment of the present invention;

FIG. 5 is a sectional view showing how the first passivation layer is etched according to an embodiment of the present invention;

FIG. 6 is a sectional view showing the step of forming a co-electrical-connecting layer according to an embodiment of the present invention;

FIG. 7 is a sectional view showing the step of depositing a second passivation layer according to an embodiment of the present invention;

FIG. 8 is a sectional view showing the step of depositing a mirror layer according to an embodiment of the present invention;

FIG. 9 is a sectional view showing the step of forming two conductive tunnels by etching according to an embodiment of the present invention;

FIG. 10 is a sectional view showing how conductive metals are filled into the conductive tunnels according to an embodiment of the present invention;

FIG. 11 is a sectional view showing the step of providing two connecting metal layers according to an embodiment of the present invention;

FIG. 12 is a sectional view showing the step of forming a plurality of microstructures according to an embodiment of the present invention;

FIG. 13 is a sectional view showing the step of connecting with a circuit board according to an embodiment of the present invention;

FIG. 14 is a sectional view of a high-voltage flip-chip LED structure according to an embodiment of the present invention; and

FIG. 15 is a sectional view showing an application of a high-voltage flip-chip LED structure according to an embodiment of the present invention.

### DETAILED DESCRIPTION OF THE INVENTION

### Embodiment of a Manufacturing Method of a High-Voltage Flip-Chip LED Structure

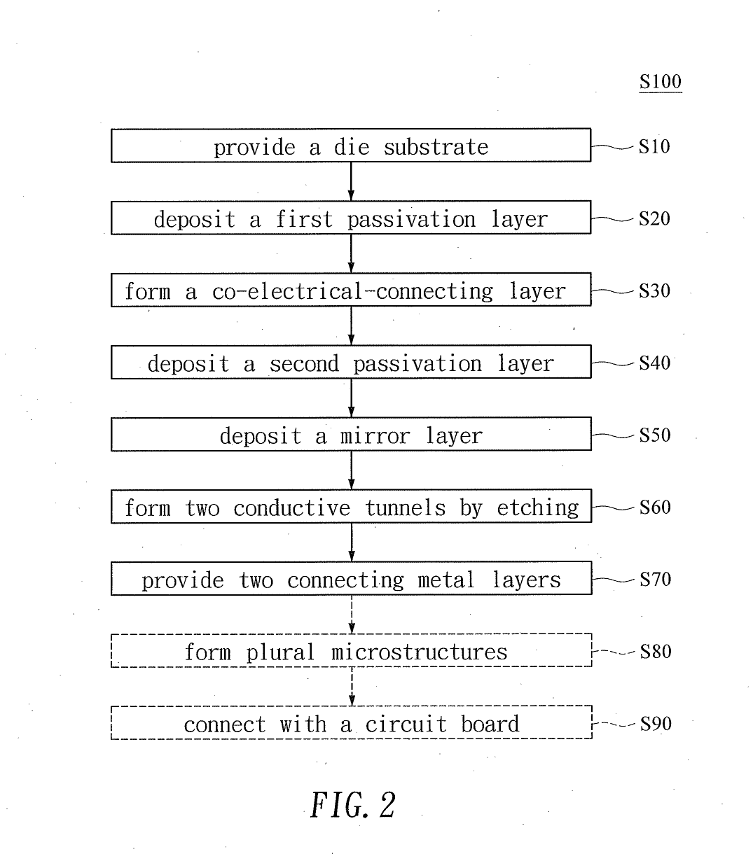

According to an embodiment of the present invention as shown in FIG. 2, a manufacturing method S100 of a high-voltage flip-chip LED structure includes the steps of providing a die substrate (step S10), depositing a first passivation layer (step S20), forming a co-electrical-connecting layer (step S30), depositing a second passivation layer (step S40), depositing a mirror layer (step S50), forming two conductive tunnels by etching (step S60), and providing two connecting metal layers (step S70).

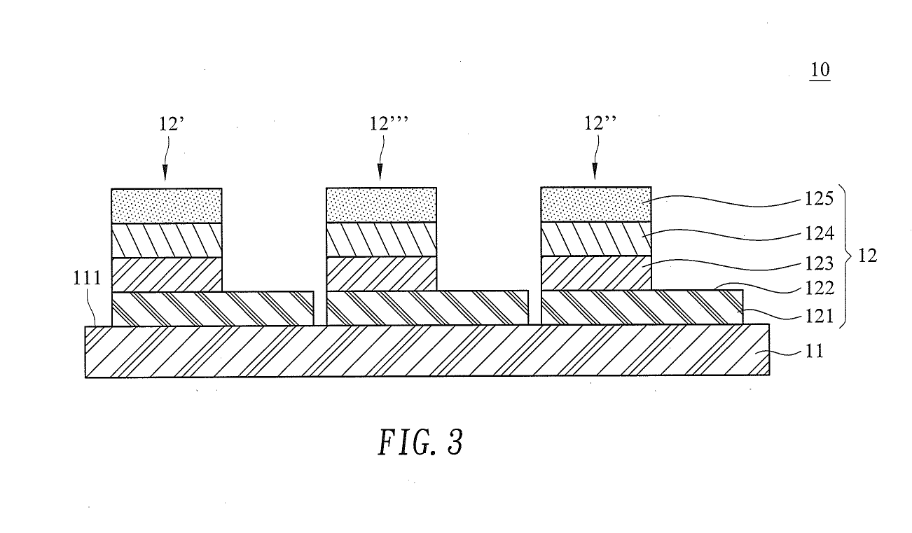

The step of providing a die substrate (step S10) is now described with reference to FIG. 3. The die substrate 10 includes: a sapphire substrate 11 and a plurality of LED chips 12. The sapphire substrate 11, to begin with, is used to grow an N-type gallium nitride layer 121 (hereinafter abbreviated as N-type layer 121), a quantum well layer 123, a P-type gallium nitride layer 124 (hereinafter abbreviated as P-type layer 124), and a transparent conductive oxide layer 125. Then, after repeated etching, the plural LED chips 12 (e.g., the LED chips 12′, 12″, and 12′ in FIG. 3) are formed on a first surface 111 of the sapphire substrate 11 and are spaced from one another, wherein the first surface 111 is an upper surface of the sapphire substrate 11. The transparent conductive oxide layer 125 is electrically conductive and is made of a transparent oxide to increase light emission efficiency.

More specifically; each LED chip 12 is formed, from bottom to top, by an epitaxial process in which the N-type layer 121, the quantum well layer 123, the P-type layer 124, and the transparent conductive oxide layer 125 are sequentially formed. Then, the transparent conductive oxide layer 125, the P-type layer 124, and the quantum well layer 123 are partially etched such that an N-type surface 122 is exposed from the N-type layer 121. In order to describe the LED chips 12 in more detail, the LED chips 12 in this embodiment are named the first LED chip 12′, the second LED chip 12″, and the third LED chip 12′ respectively. The first LED chip 12′ is the leftmost LED chip 12 on the sapphire substrate 11, the second LED chip 12″ is the rightmost LED chip 12 on the sapphire substrate 11, and the third LED chip 12′ is located between the first LED chip 12′ and the second LED chip 12″. It is also feasible to provide a plurality of third LED chips 12′.

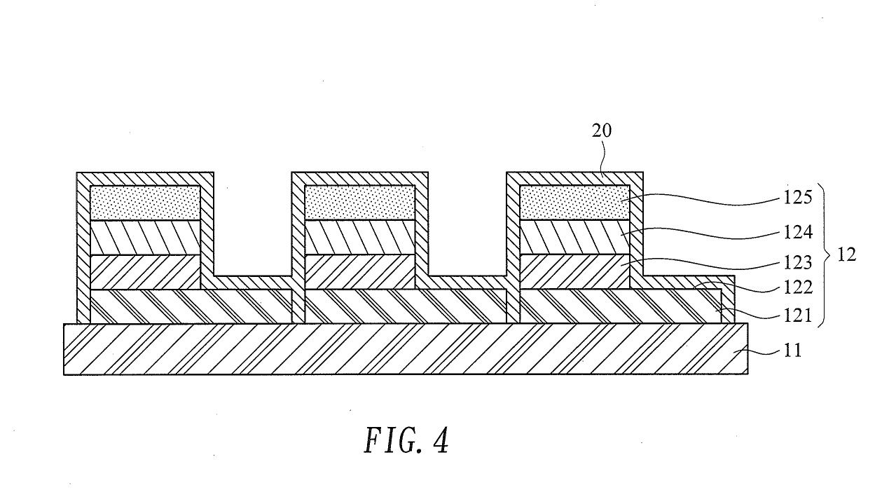

Referring to FIG. 4, the step of depositing a first passivation layer (step S20) involves depositing a first passivation layer 20 on the exposed surfaces of the LED chips. As a result, the first passivation layer 20 covers the lateral sides of each N-type layer 121, quantum well layer 123, P-type layer 124, and transparent conductive oxide layer 125; an upper surface of the sapphire substrate 11; each N-type surface 122; and an upper surface of each transparent conductive oxide layer 125.

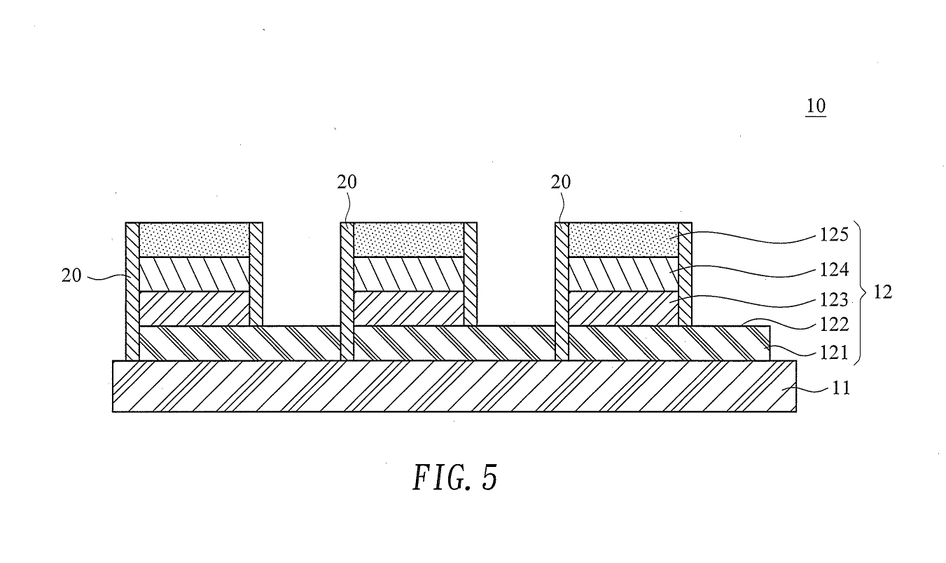

Referring to FIG. 5, the step of forming a co-electrical-connecting layer (step S30) begins with removing the first passivation layer 20 on the upper surface of each transparent conductive oxide layer 125 and on each N-type surface 122 by etching.

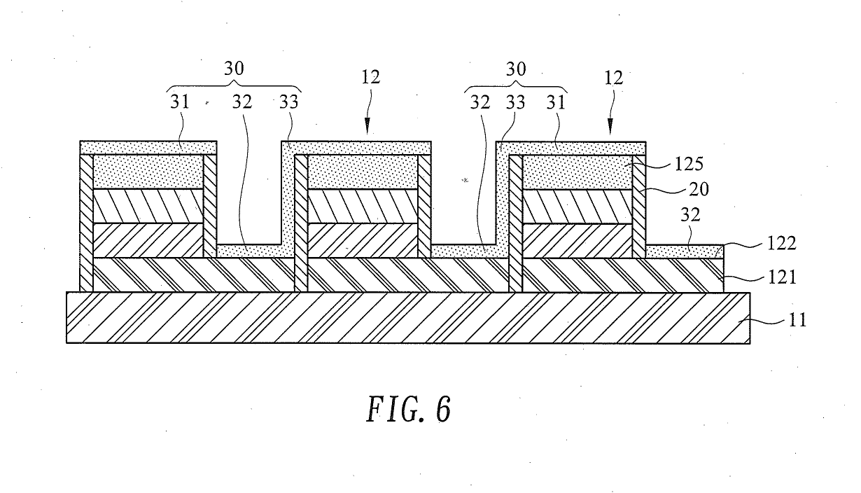

Then, as shown in FIG. 6, the step of forming a co-electrical-connecting layer (step S30) continues with forming, by deposition, a co-electrical-connecting layer 30 on the first passivation layer 20, on each exposed N-type surface 122, and on the upper surface of each transparent conductive oxide layer 125. To facilitate description, the co-electrical-connecting layer 30 is divided into a first electrical connecting layer 31, a second electrical connecting layer 32, and a third electrical connecting layer 33. The first electrical connecting layer 31 is formed on the upper surface of each transparent conductive oxide layer 125. The second electrical connecting layer 32 is formed on each N-type surface 122. The third electrical connecting layer 33 extends from the first electrical connecting layer 31 of a LED chip 12 to the second electrical connecting layer 32 of an adjacent LED chip 12 along a lateral side of the former LED chip 12. The third electrical connecting layer 33 serves to electrically connect the first electrical connecting layer 31 of a LED chip 12 to the second electrical connecting layer 32 of an adjacent LED chip 12.

With the co-electrical-connecting layer 30 connecting the plural LED chips 12 in series, a high-voltage LED structure is formed. The co-electrical-connecting layer 30 may be formed of the same material as the transparent conductive oxide layers 125 because a transparent conductive material not only provides electrical conductivity, but also prevents the co-electrical-connecting layer 30 from blocking the light emitted from the LED chips 12, thereby increasing light permeability.

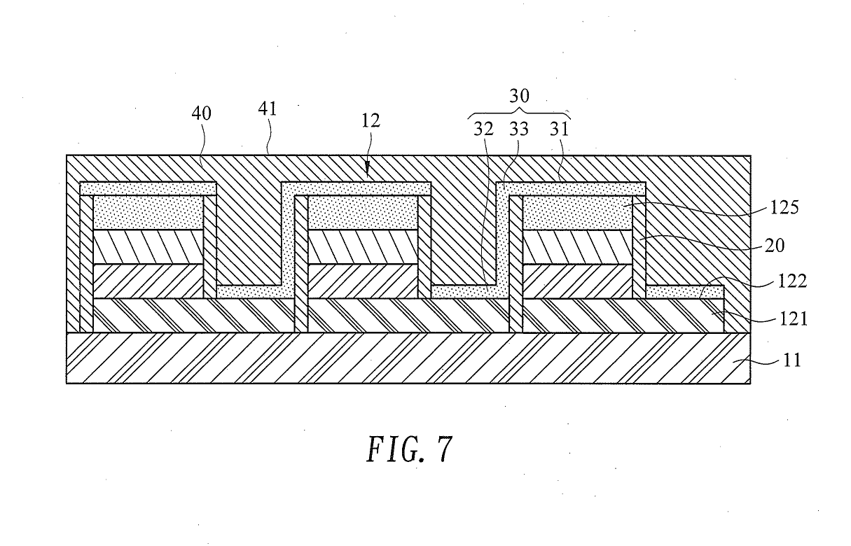

Referring to FIG. 7, the step of depositing a second passivation layer (step S40) involves depositing a second passivation layer 40 on the exposed first passivation layer 20 and co-electrical-connecting layer 30. Deposition of the second passivation layer 40 does not stop until the second passivation layer 40 covers all the LED chips 12 and forms a flat and level passivation surface 41 for subsequent processing.

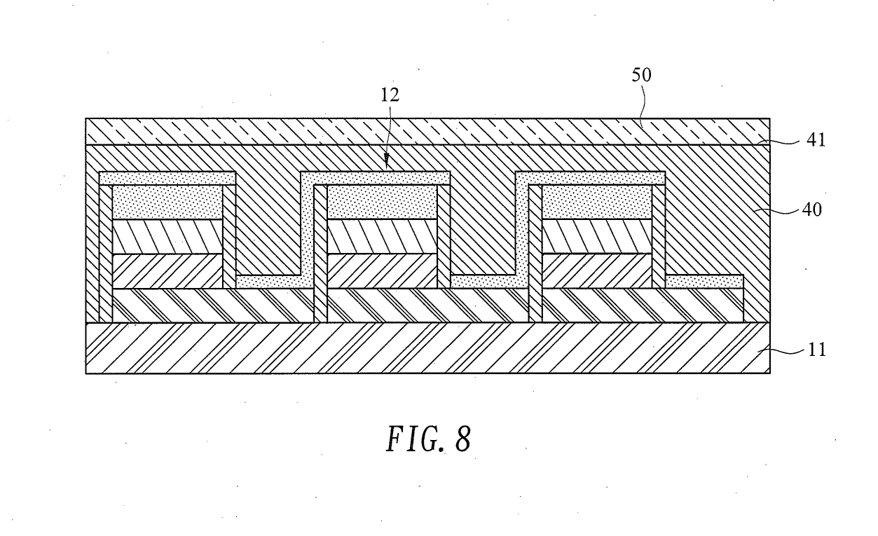

Referring to FIG. 8, the step of depositing a mirror layer (step S50) involves depositing a mirror layer 50 on the flat and level passivation surface 41, which makes the mirror layer 50 flat and level; too, allowing the light emitted by the LED chips 12 to be reflected by the mirror layer 50 at the same height. As a result, the reflection is uniform in amount and intensity and is projected toward the sapphire substrate 11 without optical path difference. The mirror layer 50 may be composed of a distributed Bragg reflector (DBR) and a metal, wherein the metal may be aluminum or silver.

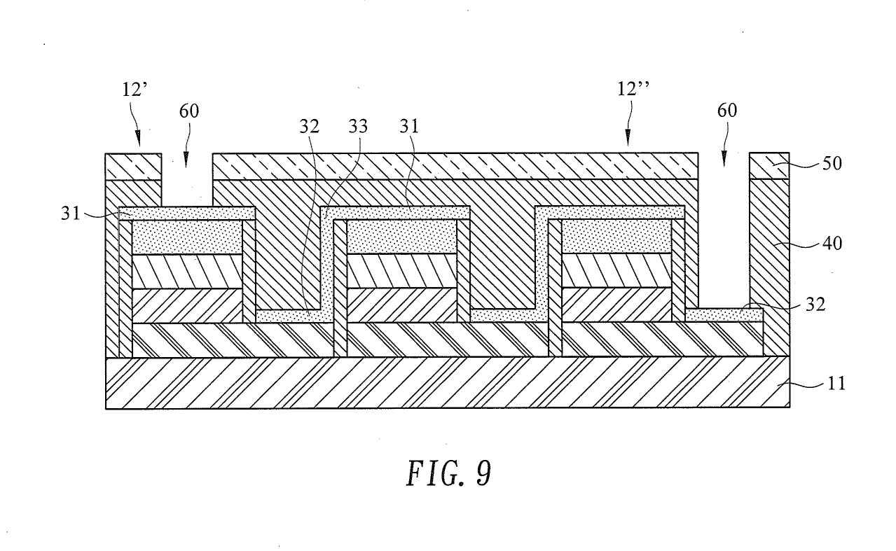

Referring to FIG. 9, the step of forming two conductive tunnels by etching (step S60) is performed as follows. To form one of the two conductive tunnels 60, etching starts from the mirror layer 50 at a position above and adjacent to the first LED chip 12′, proceeds downward through the second passivation layer 40, and stops at the first electrical connecting layer 31 of the first LED chip 12′. To form the other conductive tunnel 60, etching starts from the mirror layer 50 at a position above and adjacent to the second LED chip 12″, proceeds downward through the second passivation layer 40, and stops at the second electrical connecting layer 32 of the second LED chip 12″. Thus, the first electrical connecting layer 31 of the first LED chip 12′ and the second electrical connecting layer 32 of the second LED chip 12″ are exposed.

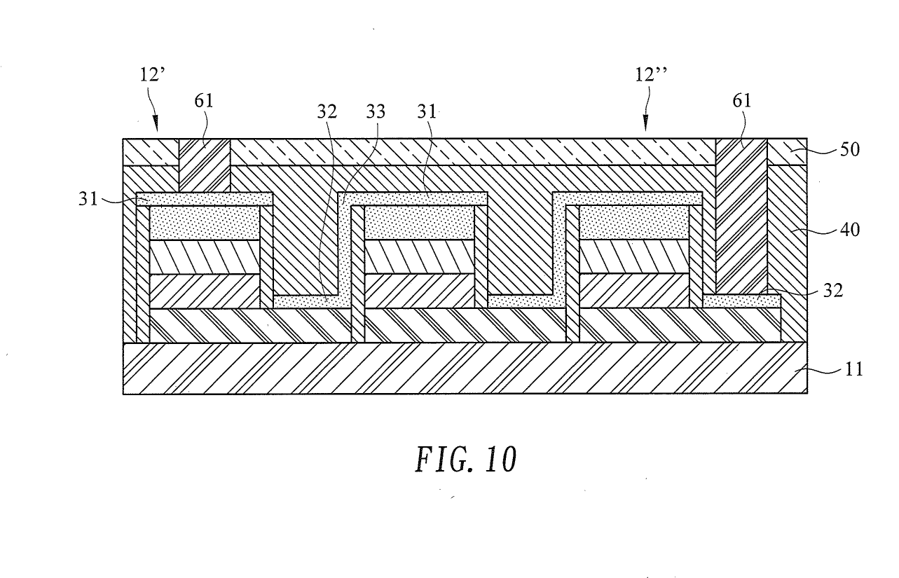

Referring to FIG. 10, the step of providing two connecting metal layers (step S70) begins with filling each conductive tunnel 60 (formed by etching in step S60) with a connecting metal 61 and making the connecting metals 61 flush with the mirror layer 50.

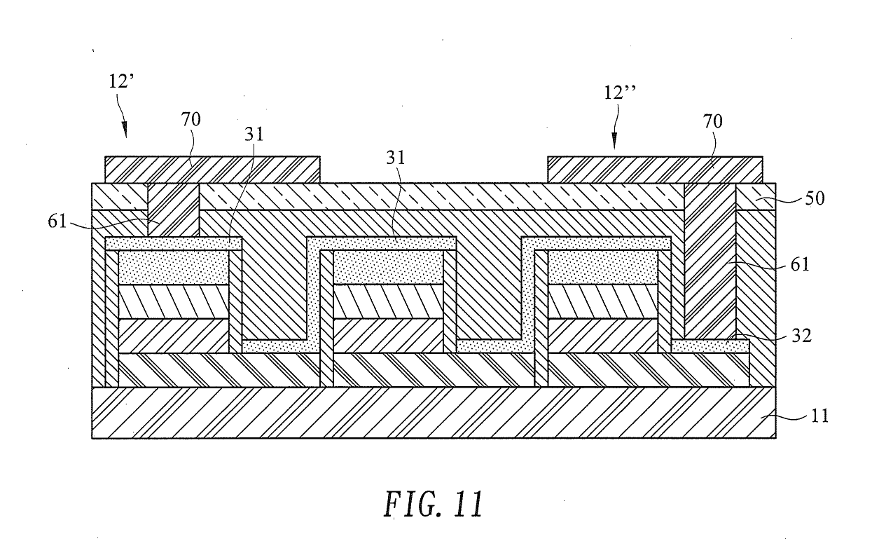

Following that, as shown in FIG. 11, two connecting metal layers 70 are provided on the mirror layer 50 in such a way that the connecting metal layers 70 are respectively connected to the connecting metals 61 to enable electrical conduction. More specifically, the connecting metal layers 70 are electrically connected to the first electrical connecting layer 31 of the first LED chip 12′ and the second electrical connecting layer 32 of the second LED chip 12″ via the corresponding connecting metals 61 respectively. The connecting metal layers 70 are spaced apart to prevent short circuits. In addition, the surfaces of the connecting metal layers 70 may be electroplated with a gold film to enhance electrical conductivity.

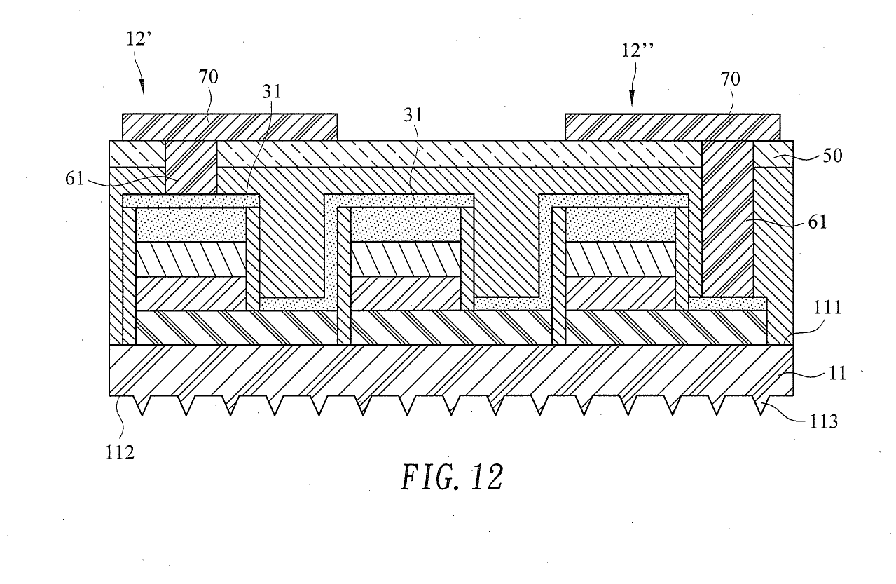

As shown in FIG. 2 and FIG. 12, the manufacturing method S100 may further include the step of forming a plurality of microstructures (step S80), in which step a second surface 112 of the sapphire substrate 11 is formed with a plurality of microstructures 113 to prevent total internal reflection. The second surface 112 is a lower surface of the sapphire substrate 11. The microstructures 113 may be cones, convex lenses, concave lenses, or the like.

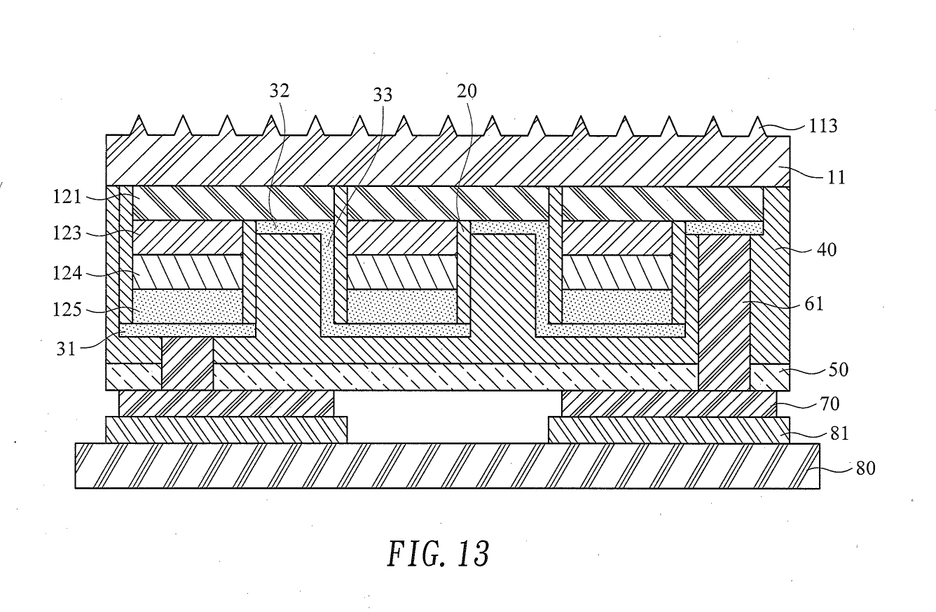

As shown in FIG. 2 and FIG. 13, the manufacturing method S100 may further include the step of connecting with a circuit board (step S90), in which step the aforesaid structure is inverted and the connecting metal layers 70 are electrically connected to a conductive metal 81 on a circuit board 80 by an electrical connection means (e.g., a metal electrode or solder balls). Thus, the high-voltage flip-chip LED structure is completed.

### Embodiment of a High-Voltage Flip-Chip LED Structure

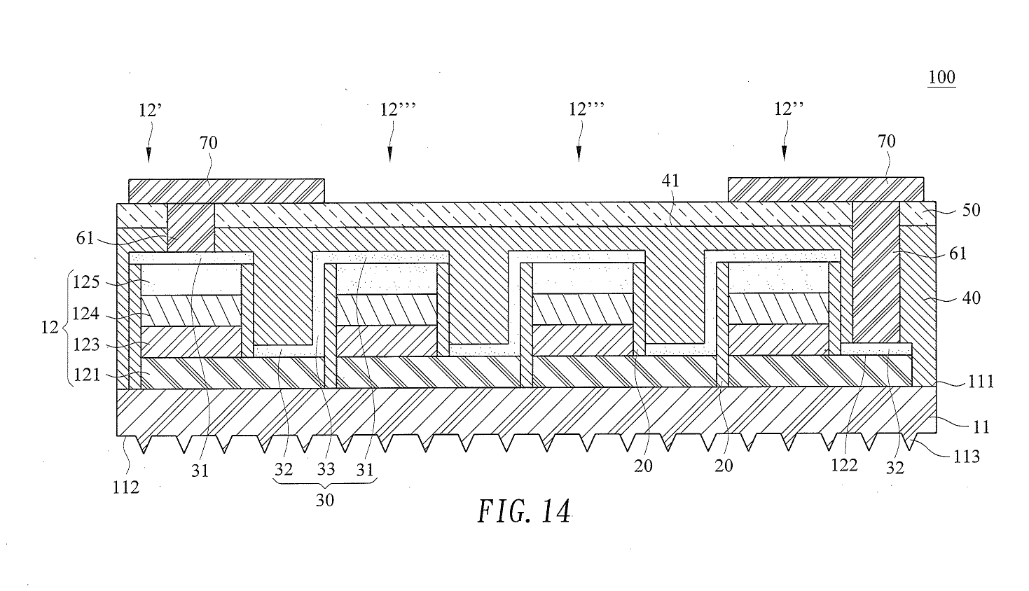

As shown in FIG. 2 and FIG. 14, a high-voltage flip-chip LED structure 100 according to an embodiment of the present invention includes: a die substrate, a first passivation layer 20, a co-electrical-connecting layer 30, a second passivation layer 40, a mirror layer 50, two connecting metals 61, and two connecting metal layers 70. The high-voltage flip-chip LED structure 100 can be made by the manufacturing method S100 described above.

The die substrate includes: a sapphire substrate 11 and a plurality of LED chips 12. The LED chips 12 are formed on a first surface 111 of the sapphire substrate 11 and are spaced from one another, wherein the first surface 111 is an upper surface of the sapphire substrate 11. A second surface 112 of the sapphire substrate 11 may include a plurality of microstructures 113 to prevent total internal reflection, wherein the second surface 112 is a lower surface of the sapphire substrate 11. The microstructures 113 may be cones, convex lenses, concave lenses, or the like.

Each LED chip 12 is formed, from bottom to top, by an N-type layer 121, a quantum well layer 123, a P-type layer 124, and a transparent conductive oxide layer 125, wherein the quantum well layer 123, the P-type layer 124, and the transparent conductive oxide layer 125 are smaller in planar area than the N-type layer 121 such that an N-type surface 122 is exposed from the bottommost N-type layer 121. The transparent conductive oxide layer 125 is electrically conductive and is made of a transparent oxide to provide increased light permeability.

In order to describe the LED chips 12 in more detail, the LED chips 12 in this embodiment are referred to as the first LED chip 12′, the second LED chip 12″, and the third LED chips 12′″ respectively. The first LED chip 12′ is the leftmost LED chip 12 on the sapphire substrate 11, the second LED chip 12″ is the rightmost LED chip 12 on the sapphire substrate 11, and the third LED chips 12′″ are located between the first LED chip 12′ and the second LED chip 12″. While there are plural (two) third LED chips 12′″ in this embodiment, it is feasible to provide only one third LED chip 12′″ instead.

The first passivation layer 20 is provided on the lateral sides of each LED chip 12, i.e., on the lateral sides of each N-type layer 121, quantum well layer 123, P-type layer 124, and transparent conductive oxide layer 125.

The co-electrical-connecting layer 30 includes: a first electrical connecting layer 31, a second electrical connecting layer 32, and a third electrical connecting layer 33. The first electrical connecting layer 31 is located on an upper surface of each transparent conductive oxide layer 125. The second electrical connecting layer 32 is located on each N-type surface 122. The third electrical connecting layer 33 connects a first electrical connecting layer 31 to an adjacent second electrical connecting layer 32 while covering the first passivation layer 20 on a lateral side of each LED chip 12. In other words, the third electrical connecting layer 33 extends from the first electrical connecting layer 31 of a LED chip 12 to the second electrical connecting layer 32 of an adjacent LED chip 12 along a lateral side of the former LED chip 12. Consequently, the plural LED chips 12 are connected in series to form a high-voltage LED structure.

The co-electrical-connecting layer 30 may be formed of the same material as the transparent conductive oxide layers 125. This is because a transparent conductive material not only provides electrical conductivity, but also prevents the co-electrical-connecting layer 30 from blocking light. The latter feature helps increase light emission efficiency.

The second passivation layer 40 encloses the first passivation layer 20 and the co-electrical-connecting layer 30 and covers all the LED chips 12 such that a flat passivation surface 41 is formed for subsequent processing.

The mirror layer 50 is provided on the passivation surface 41. As the passivation surface 41 is flat, the mirror layer 50 lying thereon is level, which enables light reflection at the same height. In consequence, the reflected light is uniform in amount and intensity and is projected toward the sapphire substrate 11 without optical path difference. The mirror layer 50 may be composed of a distributed Bragg reflector (DBR) and a metal, wherein the metal may be aluminum or silver.

One of the two connecting metals 61 extends from the surface of the mirror layer 50 at a position above and adjacent to the first LED chip 12′, passes through the mirror layer 50 and the second passivation layer 40, and is connected both physically and electrically to the first electrical connecting layer 31 of the first LED chip 12′. The other of the two connecting metals 61 extends from .the surface of the mirror layer 50 at a position above and adjacent to the second LED chip 12″, passes through the mirror layer 50 and the second passivation layer 40, and is connected both physically and electrically to the second electrical connecting layer 32 of the second LED chip 12″.

The two connecting metal layers 70 are provided on the mirror layer 50 and are respectively connected to the connecting metals 61 both physically and electrically. Moreover, the connecting metal layers 70 are spaced apart to avoid short circuits, and the surface of each connecting metal layer 70 is electroplated with a gold film to increase electrical conductivity.

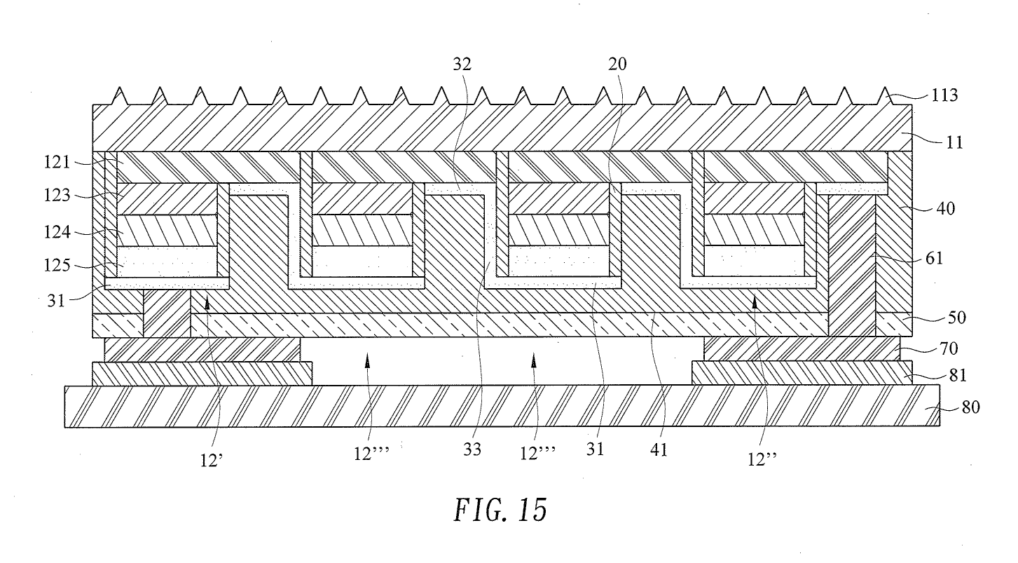

As shown in FIG. 15, the high-voltage flip-chip LED structure 100 may further include a circuit board 80. The circuit board 80 has a conductive metal 81 provided thereon and electrically connected to the connecting metal layers 70. Once electrical connection to the circuit board 80 is done, the entire structure is inverted to complete the high-voltage flip-chip LED structure 100. The circuit board 80 may be a ceramic circuit board.

The features of the present invention are disclosed above by the preferred embodiment to allow persons skilled in the art to gain insight into the contents of the present invention and implement the present invention accordingly. The preferred embodiment of the present invention should not be interpreted as restrictive of the scope of the present invention. Hence, all equivalent modifications or amendments made to the aforesaid embodiment should fall within the scope of the appended claims.

What is claimed is:

1. A manufacturing method of a high-voltage flip-chip light-emitting diode (LED) structure, comprising the steps of:
providing a die substrate, wherein the die substrate comprises: a sapphire substrate, and a plurality of LED chips formed on the sapphire substrate and spaced from one another, each said LED chip being formed, from bottom to top, by an N-type layer, a quantum well layer, a P-type layer, and a transparent conductive oxide layer, each said N-type layer having an exposed N-type surface, the LED chips comprising a first LED chip and a second LED chip;
depositing a first passivation layer on exposed surfaces of the LED chips;
forming a co-electrical-connecting layer by: removing the first passivation layer on each said transparent conductive oxide layer and on each said N-type surface, and then forming a first electrical connecting layer on each said transparent conductive oxide layer, a second electrical connecting layer on each said N-type surface, and a third electrical connecting layer connecting the first electrical connecting layer of a said LED chip and the second electrical connecting layer of an adjacent said LED chip, wherein the first electrical connecting layer, the second electrical connecting layer, and the third electrical connecting layer constitute the co-electrical-connecting layer;
depositing a second passivation layer on the first passivation layer and on the co-electrical-connecting layer such that a flat passivation surface is formed;
depositing a mirror layer on the passivation surface;
forming two conductive tunnels by: etching downward from the mirror layer to the first electrical connecting layer of the first LED chip, and etching downward from the mirror layer to the second electrical connecting layer of the second LED chip; and
providing two connecting metal layers by: filling each said conductive tunnel with a connecting metal, and providing the connecting metal layers onto the mirror layer such that the connecting metal layers are respectively connected to the connecting metals and are spaced from each other.

2. The manufacturing method of claim 1, further comprising the step of: foaming a plurality of microstructures on a backside surface of the sapphire substrate.

3. The manufacturing method of claim 1, further comprising the step of: electrically connecting the connecting metal layers to a conductive metal on a circuit board.

4. The manufacturing method of claim 1, wherein the mirror layer is composed of a distributed Bragg reflector and a metal.

5. The manufacturing method of claim 4, wherein the metal is aluminum or silver.

6. The manufacturing method of claim 1, wherein each said connecting metal layer has a surface electroplated with a gold film.

7. A high-voltage flip-chip light-emitting diode (LED) structure, comprising:
a die substrate comprising: a sapphire substrate, and a plurality of LED chips formed on the sapphire substrate and spaced from one another, each said LED chip being formed, from bottom to top, by an N-type layer, a quantum well layer, a P-type layer, and a transparent conductive oxide layer, each said N-type layer having an exposed N-type surface, the LED chips comprising a first LED chip and a second LED chip;
a first passivation layer provided on lateral sides of each said LED chip;
a co-electrical-connecting layer comprising: a first electrical connecting layer located on each said transparent conductive oxide layer, a second electrical connecting layer located on each said N-type surface, and a third electrical connecting layer connecting a said first electrical connecting layer and an adjacent said second electrical connecting layer and covering the first passivation layer on a said lateral side of each said LED chip;
a second passivation layer enclosing the first passivation layer and the co-electrical-connecting layer such that a flat passivation surface is formed;
a mirror layer provided on the passivation surface;
two connecting metals extending through the mirror layer and the second passivation layer and respectively connected to the first electrical connecting layer of the first LED chip and the second electrical connecting layer of the second LED chip; and
two connecting metal layers provided on the mirror layer, respectively connected to the connecting metals, and spaced from each other.

8. The high-voltage flip-chip LED structure of claim 7, further comprising a circuit board electrically connected to the connecting metal layers via a conductive metal.

9. The high-voltage flip-chip LED structure of claim 7, wherein the mirror layer is composed of a distributed Bragg reflector and a metal.

10. The high-voltage flip-chip LED structure of claim 9, wherein the metal is aluminum or silver.

11. The high-voltage flip-chip LED structure of claim 7, wherein each said connecting metal layer has a surface electroplated with a gold film.

12. The high-voltage flip-chip LED structure of claim 7, wherein the sapphire substrate has a backside surface comprising a plurality of microstructures.
